(19) United States
(12) Patent Application Publication
(10) Pub. No.: US 2014/0009896 A1
(43) Pub. Date: Jan. 9, 2014

(54) Converter Assembly, Method for Producing a Converter Assembly and Method for Operating a Converter Assembly

(71) Applicants: Joachim Nikola, Kraichtal (DE); Hans Juergen Kollar, Bruchsal (DE); Rolf Janzer, Bruchsal (DE); Juergen Maucher, Bad Herrenalb (DE); Thomas Wetzel, Ubstadt-Weiher (DE)

(72) Inventors: Joachim Nikola, Kraichtal (DE); Hans Juergen Kollar, Bruchsal (DE); Rolf Janzer, Bruchsal (DE); Juergen Maucher, Bad Herrenalb (DE); Thomas Wetzel, Ubstadt-Weiher (DE)

(21) Appl. No.: 14/007,231

(22) PCT Filed: Mar. 7, 2012
(86) PCT No.: PCT/EP12/01006

§ 371 Date: Sep. 24, 2013

(30) Foreign Application Priority Data
Mar. 28, 2011 (DE) 10-2011-015-327.6

(51) Int. Cl. H05K 7/00; H05K 13/00

(52) U.S. Cl. CPC H05K 7/00; H05K 13/0023
USPC 361/747; 29/592.1

(57) ABSTRACT

A converter assembly, a method for producing a converter assembly and a method for operating a converter assembly are described, in which a base module includes power electronics and control electronics. The base module includes a housing, particularly a housing part at least partially forming a housing for the power electronics and control electronics. The base module includes an electrical and mechanical interface, via which signal electronics are able to be joined to the base module with form-locking and/or force-locking, in order to form the converter assembly. The signal electronics include a housing, especially so that after being joined, the housing of the signal electronics and the housing of the base module together form a housing of the converter assembly. A setpoint value for speed and/or torque is transmittable electrically via the interface, the signal electronics having means for receiving, determining and/or inputting the setpoint value.

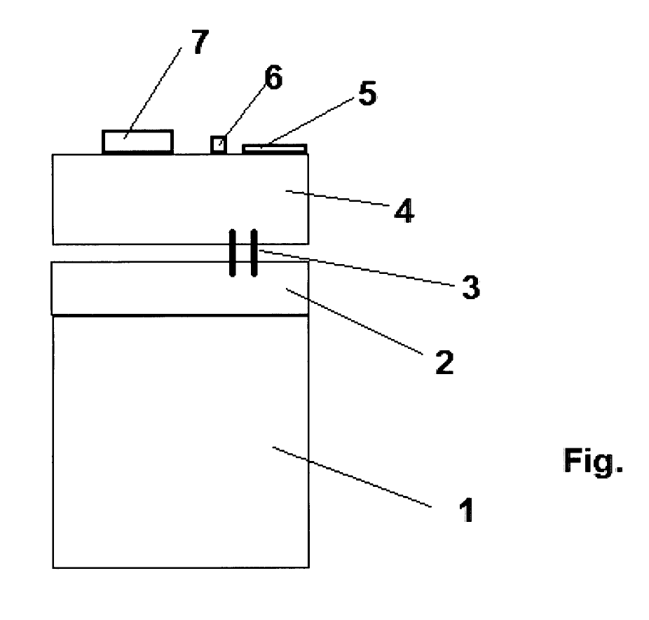

### FIELD OF INVENTION

The present invention relates to a converter assembly, a method for producing a converter assembly and a method for operating a converter assembly.

### BACKGROUND INFORMATION

European Application No. EP 0 994 559 describes a modular converter in which a power module is provided with an attachable control head and a held-held operator insertable into it.

### SUMMARY

Therefore, an object of the present invention is to achieve a cost-effective method for producing a converter assembly, in doing which, a high variance in functionality being required, depending on the application.

According to the present invention, the objective may be achieved by a converter assembly, the method for producing a converter assembly, and the method for operating a converter assembly.

Important features of the present invention in the case of the converter assembly may be that it includes a base module, power electronics and control electronics,

the base module having a housing, particularly a housing part at least partially forming a housing for power electronics and control electronics,
the base module having an electrical and mechanical interface, via which signal electronics are able to be joined to the base module with form-locking and/or force-locking, in order to form the converter assembly,
the signal electronics having a housing, especially so that after being joined, the housing of the signal electronics and the housing of the base module together form a housing of the converter assembly,
a setpoint value for speed and/or torque being transmittable electrically via the interface, the signal electronics having means for receiving, determining and/or inputting the setpoint value.

An advantage in this context may be that the converter assembly and the modular system for manufacturing it are practicable with a base module that represents a converter of limited functionality, namely, only the closed-loop control to the torque setpoint value or speed setpoint value. Input means or display means are thereby able to be omitted. Therefore, depending on the application requirement of the converter in the system provided, a suitable signal-electronics module may be connectable to the base module, so that the desired functionalities are available, especially input and display possibilities for the operator and/or desired type of data interface to connected devices.

The signal electronics may have an automatic control unit which, based on a deviation between a setpoint value of a variable, particularly of a position, and an actual value, determines a manipulated value which is transmitted as setpoint value for speed or as setpoint value for torque via the interface to the control electronics,

and/or the signal electronics may include a positioning control which determines a manipulated value as controlled variable that is transmitted as setpoint value for speed or as setpoint value for torque via the interface to the control electronics. This may have the advantage that a superordinate control is feasible in the signal electronics, so that the manipulated value determined by this automatic control unit is transmittable to the control electronics. The type of superordinate control may be selectable as a function of the application.

The control electronics may have an automatic control unit which, based on a deviation between the setpoint value supplied by the signal electronics and the actual value, determines a manipulated value for motor voltage and generates corresponding pulse-width-modulated driving signals for the power semiconductors of the power electronics which are controllable accordingly to generate the motor voltage to be adjusted. This may be advantageous in that it permits a simple and rapid closed-loop control of the motor.

One or each automatic control unit may have a linear controller, particularly a PI controller, with or without pre-control. This may have the advantage of permitting a rapidly active, effective control requiring little computational time.

The signal electronics may have means for the input and/or display of parameters, especially a touch screen, and/or connection terminals for electric lines, particularly signal lines or power-cable lines. This may offer an advantage that signal electronics consistent with the application are able to be used.

The signal electronics may have a field-bus interface. An advantage in this case may be that the interface is implemented as a function of the application.

Important features in the case of the method for producing a converter assembly may be that it is produced from a modular system, which has base modules differing from each other and signal-electronics modules differing from each other,

each base module being connectable electrically and mechanically to each signal-electronics module via the interface,
in particular, various power-electronics modules being provided for producing the base module, a suitable electrical and mechanical interface being provided between the power electronics and control electronics,
variants of converter assemblies having different functionality being assembled from the base modules and signal-electronics modules, especially depending on the requirement of the application.

This may be advantageous because, depending on the specific application and the requirements there, a converter assembly is able to be joined together and produced which satisfies the requirements, thus, in particular, has the suitable data interface and/or input/output means.

Important features in the case of the method for operating a converter assembly may be that a setpoint value for torque or speed is supplied by signal electronics via an interface to control electronics,

the acquired value for motor current and/or angular value of the rotor shaft being supplied to the control electronics, and from it, an actual value being determined for torque or speed, which is adjusted by an automatic control unit of the control electronics to the setpoint value by determining the motor voltage as manipulated value, particularly by determining corresponding pulse-width-modulated driving signals that are supplied to power semiconductor switches,
the setpoint value for torque or speed being determined by an automatic control unit of the signal electronics as manipulated value of a controlled variable of the automatic control unit of the signal electronics,
a setpoint value and an actual value of a variable, especially of a position of a part driven by the motor energized by the converter assembly, being supplied to the signal electronics, and the deviation between the setpoint value and actual value being determined, and from it, the manipulated value being determined by the automatic control unit of the signal electronics. This may be advantageous because a superordinate control consistent with the application is able to be provided in the signal electronics, the associated microcontroller or microprocessor of the signal electronics being selected accordingly. Advantageously, because of this, no additional load may be brought about for the microcontroller or microprocessor of the control electronics. In particular, the control electronics are able to be dimensioned, in terms of their computing power and memory capacity, according to the demands of the closed-loop speed control or closed-loop torque control. The signal electronics are able to be dimensioned according to the application-specific requirements, such as a large memory capacity for sequential programs in the positioning control.

The or each automatic control unit may have a linear controller, particularly a P controller, PI controller or PID controller, with or without pre-control. An advantage may be that a controller is usable which is easy to program.

Important features in the case of the torque interface or the speed interface between the signal electronics and control electronics may be that

both have a computer, particularly a microcontroller or microprocessor,
the control electronics forming a base module together with power electronics and
both computers acting as controller unit,
the controller unit of the control electronics acting as torque controller or speed controller, and the controller unit of the signal electronics acting as superordinate controller which makes the setpoint input available as controlled variable via the torque interface or speed interface to the controller unit of the control electronics.

This may have an advantage that all electronics are adaptable to the stipulated demands and no overcapacities have to be made available. In addition, reliability may be increased, since breakdowns of a simple, clear structure may be more unlikely.

Further advantages may be derived from the following description. The present invention is not limited to the feature combination described herein. Further useful combination possibilities of features will be apparent to one of ordinary skill in the art, particularly from the problem definition and/or the objectives set by comparison with the related art.

An example embodiment of the present invention will now be explained in greater detail with reference to the accompanying drawing.

### BRIEF DESCRIPTION OF THE DRAWINGS

The FIGURE schematically shows a converter according to the present invention.

### DETAILED DESCRIPTION

The converter has power electronics 1 which are connected to control electronics 2. Data is able to be exchanged with attachable signal electronics 4 via an interface 3 which, in particular, is practicable as a plug-in connection or includes such a plug-in connection.

In this context, a torque setpoint value or a speed setpoint value is transmitted by signal electronics 4 to the control electronics.

Control electronics 2 have an automatic control unit, to which this setpoint value is supplied. In addition, the automatic control unit generates pulse-width-modulated driving signals for the power semiconductors of power electronics 1. The power electronics have a rectifier to which AC voltage from the supply network is fed. The DC voltage generated by the rectifier is fed to a capacitor, from which the output stage of the power electronics, that has the power semiconductor switches disposed in half-bridges, is supplied. An electric motor, preferably a three-phase motor having motor-phase leads (U, V, W), is energized from the output stage. The current flowing to the motor is detected by sensors or shunt resistors located in the half-bridges, the motor-phase current assigned to each motor-phase lead being sensed. Alternatively, a shunt resistor may also be disposed in a current path going out from the capacitor, the shunt resistor being queried as a function of the switching states. From the motor-phase current values acquired, a motor-current space vector is formed and regulated as actual value to a setpoint value by the automatic control unit. In this context, the controlled variable of the closed-loop control system is the motor voltage produced by the pulse-width-modulated driving signals, thus, the motor-voltage space vector.

In a first realization according to the present invention, a speed value is supplied as setpoint value to the automatic control unit. Either the actual value of the speed is determined from the change in the detected motor-current space vector over time, or a speed sensor is disposed on the motor which senses the actual value of the speed of the rotor shaft of the motor and supplies it to the converter. Based on the deviation of the actual value of the speed from the setpoint value, the automatic control unit, which, for example, includes a linear controller, determines an output signal that is used to regulate the motor voltage. To that end, the pulse-width-modulated driving signals are determined from the output signal, so that the motor voltage is regulated to the determined manipulated value.

In a second realization according to the present invention, the torque is supplied as setpoint value to the automatic control unit. An actual torque value, determined using the acquired motor-current space vector, is utilized to determine the deviation of the actual value of the torque from the setpoint value of the torque. Based on the deviation, the automatic control unit, which includes a linear controller, for example, determines an output signal that is used to regulate the motor voltage. To that end, the pulse-width-modulated driving signals are determined from the output signal, so that the motor voltage is regulated to the determined manipulated value.

Thus, power module 1, together with control electronics 2, already represents a converter as such, for which a setpoint speed value and/or setpoint torque value is predefined via the interface between control electronics 2 and signal electronics 4, and which then regulates the motor voltage such that the respective actual value is regulated to the predefined setpoint value. Thus, power module 1 includes a speed controller and/or torque controller.

Power module 1 is joined together with control electronics 2 such that the two components form an electrical device with housing.

Signal electronics 4 are added on or into the electrical device formed, the electrical connections between signal electronics 4 and control electronics 2 being produced in particular by a plug-in connection. Alternatively, a contactless transmission, e.g., via radio waves or infrared waves, is also made possible.

Signal electronics 4 have connection terminals for the coupling of a field-bus connection, especially an Ethernet bus, CAN bus, Devicenet bus, Profibus or Interbus. Therefore, data is transmittable from and/or to other devices, such as a superordinate computer, connected via the field-bus connection.

In addition, signal electronics 4 have on their exterior, which is implemented so as to form a housing, a display means 5, an input means 6 and/or a touch-sensitive display means 7. Thus, parameters, especially also setpoint values, are therefore able to be input or able to be received via the field-bus connection and are able to be passed on by signal electronics 4 via the interface to control electronics 2.

Signal electronics 4 not only have a display means 5, an input means 6 and a touch-sensitive display means 7, but also connection terminals for the coupling of power cables, field-bus cabling, optical fibers and/or signal lines.

The interface produced between control electronics 2 and signal electronics 4 permits a modular structure, thus, permits a simple and rapid exchange of signal electronics 4 for other signal electronics 4 which differ in functions and/or input means and/or output means and/or have no connection terminals. Correspondingly, the power module is also exchangeable for a different power module, for example, for a power module having higher power and/or for a single-phase supply instead of a three-phase supply, since a suitable interface is present between control electronics 2 and power electronics 1. Thus, a great variety of converters is able to be produced using only a small number of components. In this context, the components form a modular system, from which the suitable component is selectable depending on the requirement, and with that, a specific converter of the overall converter series is produced.

Consequently, instead of or in addition to the indicated field-bus interface of signal electronics 4, a further bus interface and/or data interface for the exchange of data with a computer may be provided in specific signal electronics 4 of the modular system.

Thus, within the modular system, signal electronics 4 are provided which have an interface to a first bus system, e.g., a CAN bus, and other signal electronics 4 are provided which have an interface to a second bus system, e.g., Profibus.

Furthermore, signal electronics 4 may also be provided which have expanded functionalities such as a superordinate positioning control which controls a part to be moved by the motor, to a target position by determining, from the detected deviation between the actual position, which is supplied from a suitable sensor system detecting the actual position of the part, and the setpoint position, a speed value and conveying it to control electronics 2, such that the part is led to the target position. Thus, in this case, signal electronics 4 also include a position controller which adjusts the actual position to the setpoint position predefined for the specific point in time, the variation in the setpoint position with time being specifiable.

In this context, a sequencing control may also be integrated into the positioning control, in doing which, inputs and outputs for sensors and/or actuators may be provided.

Further modules may also be mounted on or in the housing of the power electronics, such as a fan module which allows a cooling-air flow to stream along the heat sink of power electronics 1 and thus improves the dissipation of heat.

In addition, a braking-resistor module is able to be added on, so that energy generated in the generator mode of the motor is able to be dissipated as heat to the surroundings. Likewise, a line filter may be installed as module which improves the electrical reactions on the feeding AC system.

Preferably, the housing of signal electronics 4 is able to be joined imperviously to the housing of the base module, which is not visible in the FIGURE, however. Thus, in particular, a seal, especially an O-ring seal or an integrally-extruded elastomer seal, is disposed between the housing of the signal electronics and the housing of the base module. The plug-in connection, thus, the electrical and mechanical interface between the base module and the signal electronics, is located in the spatial area sealed off by the two housings and therefore surrounded in a manner forming a housing. Consequently, corrosion of the connector part and mating connector part realizing the interface is prevented.

### LIST OF REFERENCE NUMERALS

1 power electronics
2 control electronics
3 interface, particularly plug-in connection
4 signal electronics
5 display means
6 input means
7 touch-sensitive display means

1-13. (canceled)

14. A converter assembly, comprising:
a base module including power electronics and control electronics, the base module having a housing or a housing part completely or at least partially forming a housing for the power electronics and control electronics,
wherein the base module includes an electrical and mechanical interface, via which signal electronics are joinable to the base module with form-locking and/or force-locking, in order to form the converter assembly,
wherein the signal electronics includes a housing such that after being joined, the housing of the signal electronics and the housing of the base module together form a housing of the converter assembly,
wherein a setpoint value for speed and/or torque is transmittable electrically via the interface, the signal electronics having means for receiving, determining and/or inputting the setpoint value.

15. The converter assembly according to claim 14, wherein the signal electronics includes an automatic control unit which, based on a deviation between a setpoint value of a variable of a position, and an actual value, determines a manipulated value which is transmitted as the setpoint value for speed and/or torque via the interface to the control electronics, and/or
wherein the signal electronics includes a positioning control which determines an instantaneous manipulated value as controlled variable that is transmitted as the setpoint value for speed and/or torque via the interface to the control electronics.

16. The converter assembly according to claim 14, wherein the control electronics includes an automatic control unit which, based on a deviation between the setpoint value supplied by the signal electronics and the actual value, determines a manipulated value for motor voltage and generates corresponding pulse-width-modulated driving signals for power semiconductors of the power electronics which are controllable accordingly to generate the motor voltage to be regulated.

17. The converter assembly according to claim 14, wherein the base module and/or the control electronics includes a speed controller and/or a torque controller, and
wherein the signal electronics includes a position controller, whose output is the setpoint value for speed and/or torque which is transmitted and predefined via the mechanical interface to the corresponding speed controller and/or torque controller in the base module and/or the control electronics.

18. The converter assembly according to claim 15, wherein the automatic control unit includes a linear controller, or a PI controller with or without pre-control.

19. The converter assembly according to claim 14, wherein the signal electronics includes means for inputting and/or displaying parameters, a touch screen, and/or connection terminals for electric lines, signal lines or power cable lines.

20. The converter assembly according to claim 14, wherein the signal electronics includes a field-bus interface.

21. The converter assembly according to claim 14, wherein the electrical and mechanical interface is implemented as a plug-in connection, the base module including a connector part and the signal electronics including a corresponding mating-connector part.

22. The converter assembly according to claim 14, wherein the housing of the signal electronics is joinable imperviously to the housing of the base module, a seal being disposed between the housing of the signal electronics and the housing of the base module, such that the electrical and mechanical interface is disposed in a spatial area surrounded and sealed off by the housings, or is surrounded by the housings in housing-forming fashion.

23. A method for producing a converter assembly, comprising:
providing a modular system including base modules differing from each other and signal-electronics modules differing from each other, each base module being connectable electrically and mechanically to each signal-electronics module via an electrical and mechanical interface, various power-electronics modules being provided for producing the base modules, the interface being provided between the power-electronics modules and the signal-electronics modules, and
assembling variants of the converter assembly having different functionality from the base modules and the signal-electronics modules, depending on requirements of an application.

24. A method for operating a converter assembly, comprising:
supplying a setpoint value for torque and/or speed by signal electronics to control electronics via an interface,
supplying an acquired value for motor current and/or angular value of a rotor shaft to the control electronics,
determining an actual value for torque and/or speed which is adjusted by an automatic control unit of the control electronics to a setpoint value by determining a motor voltage as manipulated value, or by determining corresponding pulse-width-modulated driving signals that are supplied to power semiconductor switches,
determining the setpoint value for torque and/or speed by an automatic control unit of the signal electronics as manipulated value of a controlled variable of the automatic control unit of the signal electronics,
supplying the setpoint value and an actual value of a variable of a position of a part driven by a motor energized by the converter assembly to the signal electronics, and
determining a deviation between the setpoint value and the actual value, and determining the manipulated value by the automatic control unit of the signal electronics.

25. The method according to claim 24, wherein each automatic control unit includes a linear controller, P controller, PI controller or PID controller, with or without pre-control.

26. A torque and/or speed interface between signal electronics and control electronics, each of the signal electronics and the control electronics including a computer, microcontroller or microprocessor, the control electronics forming a base module with power electronics, the computers, microcontrollers or microprocessors acting as controller units, and the controller unit of the control electronics acting as torque and/or speed controller, and the controller unit of the signal electronics acting as superordinate controller, the torque and/or speed interface comprising:
an interface via which the superordinate controller makes a setpoint input available as controlled variable to the controller unit of the control electronics.
